(19) United States
(12) Patent Application Publication
(10) Pub. No.: US 2025/0189589 A1
(43) Pub. Date: Jun. 12, 2025

(54) AUTONOMOUS BACKUP BATTERY REPLACEMENT

(71) Applicant: Dell Products L.P., Round Rock, TX (US)

(72) Inventors: Ramesh DODDAIAH, Westborough, MA (US); Daniel L. HAMLIN, Round Rock, TX (US); Manikandan R, Tirunelveli (IN); Malathi RAMAKRISHNAN, Madurai (IN)

(73) Assignee: Dell Products L.P., Round Rock, TX (US)

(21) Appl. No.: 18/535,099

(22) Filed: Dec. 11, 2023

(51) Int. Cl. G01R 31/367; G01R 31/392; H01M 50/569

(52) U.S. Cl. CPC G01R 31/367; G01R 31/392; H01M 50/569

(57) ABSTRACT

An information handling system may include at least one processor and a network interface adapter. The information handling system may be configured to: receive, via the network interface adapter, information relating to a plurality of batteries, wherein the information includes environmental data and performance data; train a machine learning model based on the received information; and based on the machine learning model, perform a predictive analysis on at least one other battery to determine a likelihood of failure.

### TECHNICAL FIELD

The present disclosure relates in general to information handling systems, and more particularly to techniques for management of backup batteries in information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Hyper-converged infrastructure (HCI) is an IT framework that combines storage, computing, and networking into a single system in an effort to reduce data center complexity and increase scalability. Hyper-converged platforms may include a hypervisor for virtualized computing, software-defined storage, and virtualized networking, and they typically run on standard, off-the-shelf servers. One type of HCI solution is the Dell EMC VxRail™ system. Some examples of HCI systems may operate in various environments (e.g., an HCI management system such as the VMware® vSphere® ESXi™ environment, or any other HCI management system). Some examples of HCI systems may operate as software-defined storage (SDS) cluster systems (e.g., an SDS cluster system such as the VMware® vSAN™ system, or any other SDS cluster system).

In the HCI context (as well as other contexts), information handling systems may execute virtual machines (VMs) for various purposes. A VM may generally comprise any program of executable instructions, or aggregation of programs of executable instructions, configured to execute a guest operating system on a hypervisor or host operating system in order to act through or in connection with the hypervisor/host operating system to manage and/or control the allocation and usage of hardware resources such as memory, central processing unit time, disk space, and input and output devices, and provide an interface between such hardware resources and application programs hosted by the guest operating system.

In an edge computing scenario, an edge gateway information handling system may be used to enable communications between other edge devices and a cloud system (e.g., a system accessible via the internet). Some information handling systems (e.g., edge gateways in the HCI context) may include backup batteries to allow them to recover volatile customer data and metadata in case of a disaster event. For example, in some embodiments, several megabytes or gigabytes of data from volatile memory (e.g., DRAM) may need to be written to non-volatile storage as part of this process. Backup batteries may be designed to maintain power for some designated number (e.g., 1, 2, or in general N) of such events. Other embodiments of this disclosure may be applicable to other situations (e.g., uninterruptible power supply batteries, laptop batteries, etc.).

Batteries are typically shipped at some specification to provide enough power to meet a service level objective for a given hardware configuration. However, external factors may contribute to unexpected battery wear and tear (e.g., temperature, number of discharge cycles, manufacturing defects, etc.), reducing the battery life and affecting the ability of the system to complete a battery-based recovery process.

Accordingly, embodiments of this disclosure may provide predictive failure analysis for such backup batteries.

Some embodiments of this disclosure may employ artificial intelligence (AI) techniques such as machine learning (ML), deep learning, etc. Generally speaking, machine learning encompasses a branch of data science that emphasizes methods for enabling information handling systems to construct analytic models that use algorithms that learn interactively from data. It is noted that, although disclosed subject matter may be illustrated and/or described in the context of a particular AI paradigm, such a system, method, architecture, or application is not limited to those particular techniques and may encompass one or more other AI solutions.

It should be noted that the discussion of a technique in the Background section of this disclosure does not constitute an admission of prior-art status. No such admissions are made herein, unless clearly and unambiguously identified as such.

### SUMMARY

In accordance with the teachings of the present disclosure, the disadvantages and problems associated with management of batteries in information handling systems may be reduced or eliminated.

In accordance with embodiments of the present disclosure, an information handling system may include at least one processor and a network interface adapter. The information handling system may be configured to: receive, via the network interface adapter, information relating to a plurality of batteries, wherein the information includes environmental data and performance data; train a machine learning model based on the received information; and based on the machine learning model, perform a predictive analysis on at least one other battery to determine a likelihood of failure.

In accordance with these and other embodiments of the present disclosure, a method may include an information handling system receiving information relating to a plurality of batteries, wherein the information includes environmental data and performance data; the information handling system training a machine learning model based on the received information; and based on the machine learning model, the information handling system performing a predictive analysis on at least one other battery to determine a likelihood of failure.

In accordance with these and other embodiments of the present disclosure, an article of manufacture may include a non-transitory, computer-readable medium having computer-executable instructions thereon that are executable by a processor of an information handling system for: receiving information relating to a plurality of batteries, wherein the information includes environmental data and performance data; training a machine learning model based on the received information; and based on the machine learning model, performing a predictive analysis on at least one other battery to determine a likelihood of failure.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which reference numbers indicate like features, and wherein:

FIG. 1 illustrates a block diagram of an example information handling system, in accordance with embodiments of the present disclosure;

FIG. 2 illustrates a graph of battery charge state as a function of discharge cycles, in accordance with embodiments of the present disclosure; and

FIG. 3 illustrates a graph of battery charge state as a function of temperature, in accordance with embodiments of the present disclosure.

### DETAILED DESCRIPTION

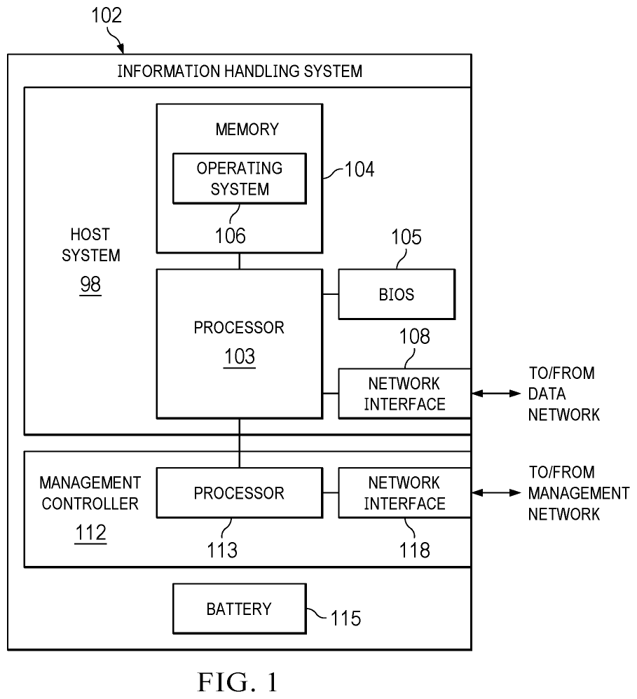

Preferred embodiments and their advantages are best understood by reference to FIGS. 1 through 3, wherein like numbers are used to indicate like and corresponding parts.

For the purposes of this disclosure, the term “information handling system” may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may in vary size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For purposes of this disclosure, when two or more elements are referred to as “coupled” to one another, such term indicates that such two or more elements are in electronic communication or mechanical communication, as applicable, whether connected directly or indirectly, with or without intervening elements.

When two or more elements are referred to as “coupleable” to one another, such term indicates that they are capable of being coupled together.

For the purposes of this disclosure, the term “computer-readable medium” (e.g., transitory or non-transitory computer-readable medium) may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; communications media such as wires, optical fibers, microwaves, radio waves, and other electromagnetic and/or optical carriers; and/or any combination of the foregoing.

For the purposes of this disclosure, the term “information handling resource” may broadly refer to any component system, device, or apparatus of an information handling system, including without limitation processors, service processors, basic input/output systems, buses, memories, I/O devices and/or interfaces, storage resources, network interfaces, motherboards, and/or any other components and/or elements of an information handling system.

For the purposes of this disclosure, the term “management controller” may broadly refer to an information handling system that provides management functionality (typically out-of-band management functionality) to one or more other information handling systems. In some embodiments, a management controller may be (or may be an integral part of) a service processor, a baseboard management controller (BMC), a chassis management controller (CMC), or a remote access controller (e.g., a Dell Remote Access Controller (DRAC) or Integrated Dell Remote Access Controller (iDRAC)).

FIG. 1 illustrates a block diagram of an example information handling system 102, in accordance with embodiments of the present disclosure. In some embodiments, information handling system 102 may comprise a server chassis configured to house a plurality f servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data (which may generally be referred to as “physical storage resources”). As shown in FIG. 1, information handling system 102 may comprise a processor 103, a memory 104 communicatively coupled to processor 103, a BIOS 105 (e.g., a UEFI BIOS) communicatively coupled to processor 103, a network interface 108 communicatively coupled to processor 103, and a management controller 112 communicatively coupled to processor 103.

In operation, processor 103, memory 104, BIOS 105, and network interface 108 may comprise at least a portion of a host system 98 of information handling system 102. In addition to the elements explicitly shown and described, information handling system 102 may include one or more other information handling resources.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may include any system, device, or apparatus configured to retain program instructions and/or data for a period of time (e.g., computer-readable media). Memory 104 may include RAM, EEPROM, a PCMCIA card, flash memory, magnetic storage, opto-magnetic storage, or any suitable selection and/or array of volatile or non-volatile memory that retains data after power to information handling system 102 is turned off.

As shown in FIG. 1, memory 104 may have stored thereon an operating system 106. Operating system 106 may comprise any program of executable instructions for aggregation of programs of executable instructions) configured to manage and/or control the allocation and usage of hardware resources such as memory, processor time, disk space, and input and output devices, and provide an interface between such hardware resources and application programs hosted by operating system 106. In addition, operating system 106 may include all or a portion of a stack for network communication via a network interface (e.g., network interface 108 for communication over a data network). Although operating system 106 is shown in FIG. 1 as stored in memory 104, in some embodiments operating system 106 may be stored in storage media accessible to processor 103, and active portions of operating system 106 may be transferred from such storage media to memory 104 for execution by processor 103.

Network interface 108 may comprise one or more suitable systems, apparatuses, or devices operable to serve as an interface between information handling system 102 and one or more other information handling systems via an in-band network. Network interface 108 may enable information handling system 102 to communicate using any suitable transmission protocol and/or standard. In these and other embodiments, network interface 108 may comprise a network interface card, or “NIC.” In these and other embodiments, network interface 108 may be enabled as a local area network (LAN)-on-motherboard (LOM) card.

Management controller 112 may be configured to provide management functionality for the management of information handling system 102. Such management may be made by management controller 112 even if information handling system 102 and/or host system 98 are powered off or powered to a standby state. Management controller 112 may include a processor 113, memory, and a network interface 118 separate from and physically isolated from network interface 108.

As shown in FIG. 1, processor 113 of management controller 112 may be communicatively coupled to processor 103. Such coupling may be via a Universal Serial Bus (USB), System Management Bus (SMBus), and/or one or more other communications channels.

Network interface 118 may be coupled to a management network, which may be separate from and physically isolated from the data network as shown. Network interface 118 of management controller 112 may comprise any suitable system, apparatus, or device operable to serve as an interface between management controller 112 and one or more other information handling systems via an out-of-band management network. Network interface 118 may enable management controller 112 to communicate using any suitable transmission protocol and/or standard. In these and other embodiments, network interface 118 may comprise a network interface card, or “NIC.” Network interface 118 may be the same type of device as network interface 108, or in other embodiments it may be a device of a different type.

Information handling system 102 may also include (or be coupled to) battery 115, which may provide backup power during emergency events.

As discussed above, embodiments of this disclosure provide improvements in the management of battery 115, providing predictive analysis of its potential failure. It should be noted that while the scenario of a backup battery in an edge gateway deployment is discussed in detail herein for the sake of concreteness, other embodiments are also specifically contemplated within the scope of this disclosure.

Embodiments of this disclosure may use ML regression models and/or other AI techniques to classify batteries based on the number of back-to-back recovery cycles that they are predicted to be able to sustain across different hardware configurations. Other embodiments may classify batteries based on different metrics (e.g., how much their post-recovery charge state has degraded since they were new, etc.).

Embodiments may rely on large numbers of measurements of the actual recovery performance and charge state of field, batteries in the including data regarding temperature, discharge cycles, a battery's internal estimate of its own remaining battery lifetime, and/or other factors. Each factor's weights and contributions to the battery classification may be learned by the model to help an administrator understand the reasons underlying the good or bad battery conditions. Learned thresholds may then be used to assign a battery to the appropriate classification (e.g., good, marginal, high-risk, etc.). Recommendations may then be made to the system administrator to replace batteries based on early detection of problems if they cannot meet their service level objectives.

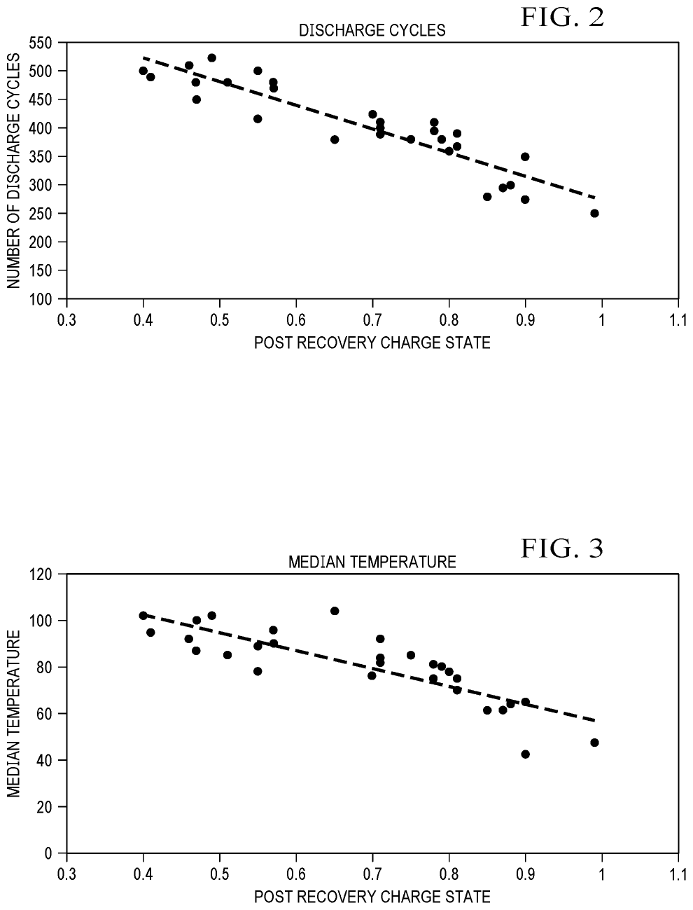

FIG. 2 shows a graph of how post-recovery charge (PRC) varies with the number of battery discharge cycles. FIG. 3 shows a graph of how post-recovery charge varies with the median temperature during the battery's service life. A linear equation may be used in some embodiments to predict an estimated PRC as follows with weights W₁, W₂, and W₃:

$$P R {C}_{est} = {W}_{1} \cdot Temp + {W}_{2} \cdot Discharges + {W}_{3} \cdot BattLife$$

where Temp refers to the battery's median temperature, Discharges refers to the number of charge/discharge cycles, and BattLife refers to the battery's own internal estimate of its health/remaining life.

Gradient descent may be used to tune the weights of an ML model based on data such as the data shown in FIGS. 2-3 (as well as similar data for other factors in some embodiments).

The trained model may then be used to determine the main risk factor(s) for each specific battery in the field.

This allows for a predictive system that can explain to an administrator why a battery should be replaced (e.g., what the main risk factors are that have contributed to its poor health). The administrator may then address those factors separately, in addition to replacing the failing battery. For example, if temperature is the main risk factor in a given datacenter, then improved cooling may be called for, etc.

Various other responsive actions may also be taken when a battery is detected that should be replaced. For example, a warning (e.g., an email) may be sent to an administrator, a replacement battery may be automatically dispatched from the manufacturer, a failing battery may be disabled, a hot spare battery may be enabled in place of the failing battery, an information handling system may be placed in a degraded operational state, an information handling system may be powered down, etc.

In some embodiments, any of various factors may be used to estimate a battery's PRC. For example, charge states, temperatures, system loads, internal battery life estimates, prior discharge events and times, etc. may all be used. Such data may be collected periodically from a variety of customer systems (e.g., via a management controller such as a BMC, a software agent running under the host operating system, etc.) and analyzed in a central system to build the ML model.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

Further, reciting in the appended claims that a structure is “configured to” or “operable to” perform one or more tasks is expressly intended not to invoke 35 U.S.C. § 112 (f) for that claim element. Accordingly, none of the claims in this application as filed are intended to be interpreted as having means-plus-function elements. Should Applicant wish to invoke § 112 (f) during prosecution, Applicant will recite claim elements using the “means for [performing a function]” construct.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. An information handling system comprising:
at least one processor; and
a network interface adapter;
wherein the information handling system is configured to:
receive, via the network interface adapter, information relating to a plurality of batteries, wherein the information includes environmental data and performance data;
train a machine learning model based on the received information; and
based on the machine learning model, perform a predictive analysis on at least one other battery to determine a likelihood of failure.

2. The information handling system of claim 1, wherein the at least one other battery is a component of a hyper-converged infrastructure (HCI) system.

3. The information handling system of claim 2, wherein the at least one other battery is a component of an edge gateway of the HCI system.

4. The information handling system of claim 1, wherein the battery is a component of an uninterruptible power supply (UPS).

5. The information handling system of claim 1, wherein the environmental data includes temperature data.

6. The information handling system of claim 1, wherein the performance data includes a number of discharge cycles.

7. A method comprising:
an information handling system receiving information relating to a plurality of batteries, wherein the information includes environmental data and performance data;
the information handling system training a machine learning model based on the received information; and
based on the machine learning model, the information handling system performing a predictive analysis on at least one other battery to determine a likelihood of failure.

8. The method of claim 7, further comprising sending a warning message in response to the likelihood of failure being above a threshold likelihood.

9. The method of claim 8, wherein the warning message includes data regarding a most-significant factor contributing to the likelihood of failure being above the threshold likelihood.

10. The method of claim 7, further comprising dispatching a replacement battery in response to the likelihood of failure being above a threshold likelihood.

11. The method of claim 7, further comprising enabling a spare battery in response to the likelihood of failure being above a threshold likelihood.

12. The method of claim 7, wherein the machine learning model is configured to implement a linear model.

13. The method of claim 7, wherein the information relating to the plurality of batteries is received from one or more management controllers.

14. The method of claim 7, wherein the information relating to the plurality of batteries is received from one or more host operating system software agents.

15. An article of manufacture comprising a non-transitory, computer-readable medium having computer-executable instructions thereon that are executable by a processor of an information handling system for:
receiving information relating to a plurality of batteries, wherein the information includes environmental data and performance data;
training a machine learning model based on the received information; and
based on the machine learning model, performing a predictive analysis on at least one other battery to determine a likelihood of failure.

16. The article of claim 15, wherein the at least one other battery is a component of a hyper-converged infrastructure (HCI) system.

17. The article of claim 16, wherein the at least one other battery is a component of an edge gateway of the HCI system.

18. The article of claim 15, wherein the battery is a component of an uninterruptible power supply (UPS).

19. The article of claim 15, wherein the environmental data includes temperature data.

20. The article of claim 15, wherein the performance data includes a number of discharge cycles.
